(19) United States
(12) Patent Application Publication
(10) Pub. No.: US 2014/0367043 A1
(43) Pub. Date: Dec. 18, 2014

(54) METHOD FOR FAST AND REPEATABLE PLASMA IGNITION AND TUNING IN PLASMA CHAMBERS

(71) Applicant: APPLIED MATERIALS, INC., Santa Clara, CA (US)

(72) Inventors: WAHEB BISHARA, Menlo Park, CA (US); SAMER BANNA, San Jose, CA (US)

(73) Assignee: APPLIED MATERIALS, INC., Santa Clara, CA (US)

(21) Appl. No.: 14/287,480

(22) Filed: May 27, 2014

Related U.S. Application Data
(60) Provisional application No. 61/835,847, filed on Jun. 17, 2013.

(51) Int. Cl. H01J 37/32

(52) U.S. Cl. CPC H01J 37/32183
USPC 156/345.28; 315/111.21

(57) ABSTRACT

Embodiments of the present invention include methods and apparatus for plasma processing in a process chamber using an RF power supply coupled to the process chamber via a matching network. In some embodiments, the method includes providing RF power to the process chamber by the RF power supply at a first frequency while the matching network is in a hold mode, adjusting the first frequency, using the RF power supply, to a second frequency during a first time period to ignite the plasma, adjusting the second frequency, using the RF power supply, to a known third frequency during a second time period while maintaining the plasma, and changing an operational mode of the matching network to an automatic tuning mode to reduce a reflected power of the RF power provided by the RF power supply.

### CROSS-REFERENCE TO RELATED APPLICATIONS

This application claims benefit of U.S. provisional patent application Ser. No. 61/835,847, filed Jun. 17, 2013, which is herein incorporated by reference.

### FIELD

Embodiments of the present invention generally relate to substrate processing systems and, more specifically, to methods and apparatus for fast and repeatable plasma ignition and tuning in plasma chambers.

### BACKGROUND

In integrated circuit manufacturing, plasma chambers are used to process substrates. A plasma chamber is typically coupled to a radio frequency (RF) source to provide energy to ignite and/or maintain a plasma during substrate processing. To effectively couple RF energy to the chamber, a matching network (also referred to as a tunable matching circuit or match box) is connected between the RF source and the plasma chamber.

Past techniques for igniting (i.e., striking) the plasma in plasma chambers, or tuning across plasma transitions, include using match boxes with motorized variable capacitors to ignite the plasma. However, the inventors have observed that this method can be slow due to the slow speed of the capacitor stepper motors (e.g., in the range of 0.5-2.0 seconds). In addition, this method suffers from poor repeatability. Specifically, the inventors have observed that in plasma chambers that require high voltages to ignite a plasma, those high voltages may not be reachable using the match box. Depending on the match box characteristics, the trajectory of the match capacitor position of may miss the high voltage point or reach it with varying delay.

Another technique for igniting plasmas, or tuning across plasma transitions, is the use of frequency sweeping of the RF power generators to reach high voltages in plasma chamber to assist in plasma striking. The inventors have observed that although this method can be fast to ignite plasma (<0.5 s), the variation in generator frequency can lead to variation in on-wafer process results and variation in RF measurement results.

Therefore, the inventors believe that there is a need in the art for improved methods and apparatus for fast and repeatable plasma ignition and/or tuning across plasma transitions in plasma chambers.

### SUMMARY

Embodiments of the present invention include methods and apparatus for plasma processing in a process chamber using an RF power supply coupled to the process chamber via a matching network. In some embodiments, an apparatus for plasma processing in a process chamber may include a first RF power supply having frequency tuning, a first matching network coupled to the first RF power supply, and a controller to control the first RF power supply and the first matching network, wherein the controller is configured to: initiate a plasma transition by at least one of instructing the RF power supply to provide RF power to the process chamber, instructing the RF power supply to change a level of RF power delivered to the process chamber, or changing a pressure in the process chamber, wherein the RF power supply operate at a first frequency and the matching network is in a hold mode, instruct the RF power supply to adjust the first frequency to a second frequency during a first time period to ignite the plasma, instruct the RF power supply to adjust the second frequency to a known third frequency during a second time period while maintaining the plasma, and change an operational mode of the matching network to an automatic tuning mode to reduce a reflected power of the RF power provided by the RF power supply.

In some embodiments, the method includes initiating a plasma transition by at least one of providing RF power to the process chamber, changing level of RF power delivered to the process chamber, or changing a pressure in the process chamber, wherein the RF power supply is operating at a first frequency and the matching network is in a hold mode, adjusting the first frequency, using the RF power supply, to a second frequency during a first time period to ignite the plasma, adjusting the second frequency, using the RF power supply, to a known third frequency during a second time period while maintaining the plasma, and changing an operational mode of the matching network to an automatic tuning mode to reduce a reflected power of the RF power provided by the RF power supply.

In some embodiments, a system for plasma processing in a process chamber may include a process chamber having an antenna assembly and a substrate support pedestal, a first matching network coupled to the antenna assembly;

a first RF source coupled to the first matching network, a matching network, a second matching network coupled to the substrate support pedestal, a second RF source coupled to the second matching network, a controller to control the first RF source, the first matching network, the second RF source, and the second controller, wherein the controller is configured to: instructing the first RF source to provide RF power to the process chamber, wherein the first source operates at a first frequency and the first matching network is in a hold mode; instruct the first RF source to adjust the first frequency to a second frequency during a first time period to ignite the plasma; instruct the first RF source to adjust the second frequency to a known third frequency during a second time period while maintaining the plasma; and change an operational mode of the first matching network to an automatic tuning mode to reduce a reflected power of the RF power provided by the first RF source.

Other and further embodiments are provided in the detailed description, below.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic diagram of a semiconductor wafer processing system in accordance with some embodiments of the present invention.

FIG. 2 is an exemplary matching network suitable for use in connection with some embodiments of the present invention.

FIG. 3 is a schematic chart showing the timing features of matching networks and RF generators in accordance with some embodiments of the present invention.

FIG. 4 is a schematic chart showing a timing diagram of frequencies provided by matching networks and RF generators in accordance with some embodiments of the present invention.

FIG. 5 depicts a flow diagram of a method for igniting a plasma and reducing a reflected power in a process chamber.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Embodiments of the present invention include methods and apparatus for igniting a plasma and/or reducing a reflected power in a process chamber across a plasma transition. Exemplary embodiments of the present invention provide methods and apparatus that combine a mechanical matching network and a variable frequency RF power generator with a set of timing rules. By operating the two tuning techniques in the appropriate order and timing, fast and repeatable plasma ignition and/or tuning is possible, with a repeatable end frequency and plasma distribution. In some embodiments, the combined system for fast and repeatable plasma ignition and/or tuning may facilitate better process performance in terms of run-to-run and wafer-to-wafer repeatability of on-wafer process results Embodiments of the present invention provide procedures that enable a repeatable and stable window of operation for using RF generators having frequency tuning (also referred to as frequency sweep) in combination with dynamic matching networks. As the time needed to get the plasma ignited and/or the system tuned is critical during, for example, etch processes, one advantage of these procedures is being able to ignite and tune a plasma within less than about 0.5 seconds, thereby minimizing the time during which the substrate is exposed to an unstable plasma or a plasma which is not well controlled. Although the description below may refer to certain processes, RF frequencies, and RF powers, the teachings provided herein may generally be utilized to advantage for other processes, other frequencies, and other power levels.

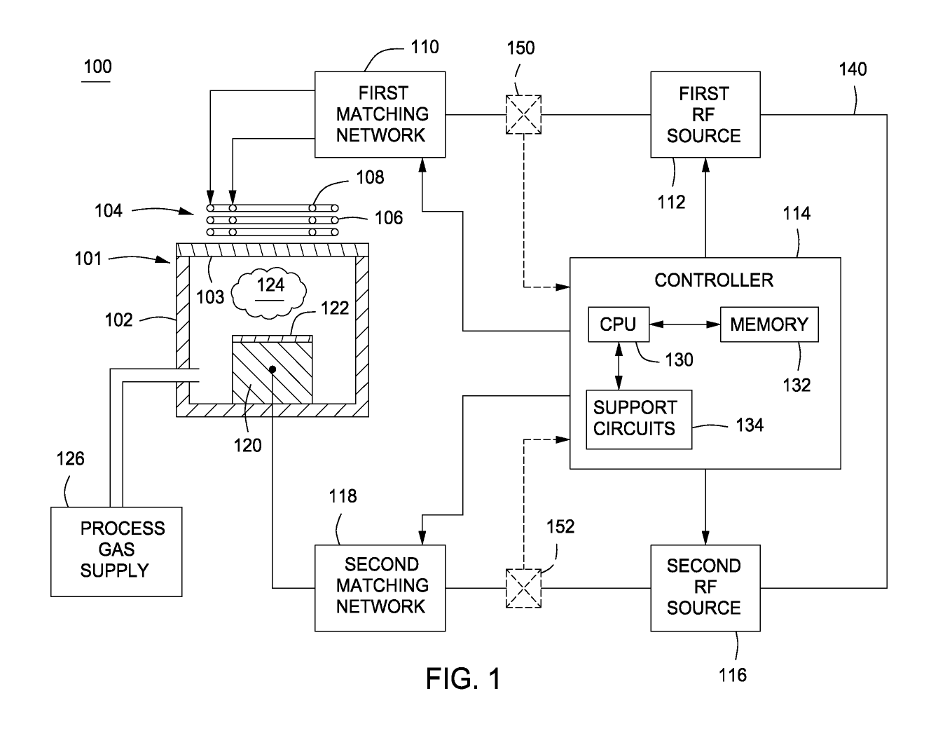

FIG. 1 is a plasma enhanced substrate processing system 100 that in some embodiments is used for processing semiconductor wafers 122 (or other substrates and work pieces). Although disclosed embodiments of the invention is described in the context of an etch reactor and semiconductor wafer etch process, the invention is applicable to any form of plasma process that uses RF power during a plasma enhanced process and where other substrates are used. Such reactors include Inductively Coupled Plasma (ICP) reactors, Capacitively Coupled Plasma (CCP) reactors and reactors for plasma annealing, plasma enhanced chemical vapor deposition, physical vapor deposition, plasma cleaning, and the like.

This illustrative plasma enhanced substrate processing system 100 comprises a plasma reactor 101, a process gas supply 126, a controller 114, a first RF power supply 112, a second RF power supply 116, a first matching network 110 (also referred to as a tunable matching circuit or a match box), and a second matching network 118. Either or both of the first and second RF power supplies 112, 116 may be configured for fast plasma ignition and fast frequency tuning (e.g., the source may be able to vary frequency within about +1-5 percent in response to a sensed reflected power measurement in order to minimize reflected power). Such frequency ignition and tuning may require about 100 micro-seconds or much less to ignite the plasma and minimize the reflected power from a plasma in a given steady state. In some embodiments described herein, a forward power is the RF power supplied by the RF power supplies 112, 116 and the reflected power is the RF power that is reflected back to the RF power supplies 112, 116.

The plasma reactor 101, or process chamber, comprises a vacuum vessel 102 that contains a cathode pedestal 120 that forms a pedestal for the wafer 122. A roof or lid 103 of the process chamber has at least one antenna assembly 104 proximate the lid 103. The lid 103 may be made of a dielectric material. The antenna assembly 104, in some embodiments of the invention, comprises a pair of antennas 106 and 108. Other embodiments of the invention may use one or more antennas or may use an electrode in lieu of an antenna to couple RF energy to a plasma. In this particular illustrative embodiment, the antennas 106 and 108 inductively couple energy to the process gas or gases supplied by the process gas supply 126 to the interior of the vessel 102. The RF energy supplied by the antennas 106 and 108 is inductively coupled to the process gases to form a plasma 124 in a reaction zone above the wafer 122. The reactive gases will etch the materials on the wafer 122.

In some embodiments, the power provided to the antenna assembly 104 ignites the plasma 124 and power coupled to the cathode pedestal 120 controls the plasma 124. As such, RF energy is coupled to both the antenna assembly 104 and the cathode pedestal 120. The first RF power supply 112 (also referred to as a source RF power supply) supplies energy to a first matching network 110 that then couples energy to the antenna assembly 104. Similarly, a second RF power supply 116 (also referred to as a bias RF power supply) couples energy to a second matching network 118 that couples energy to the cathode pedestal 120. A controller 114 controls the timing and level of activating and deactivating the RF power supplies 112 and 116 as well as tuning the first and second matching networks 110 and 118. The power coupled to the antenna assembly 104 known as the source power and the power coupled to the cathode pedestal 120 is known as the bias power.

In some embodiments, a link 140 may be provided to couple the first and second RF supplies 112, 116 to facilitate synchronizing the operation of one source to the other. Either RF source may be the lead, or master, RF generator, while the other generator follows, or is the slave. The link 140 may further facilitate operating the first and second RF supplies 112, 116 in perfect synchronization, or in a desired offset, or phase difference.

A first indicator device, or sensor, 150 and a second indicator device, or sensor, 152 are used to determine the effectiveness of the ability of the matching networks 110, 118 to match to the plasma 124. In some embodiments, the indicator devices 150 and 152 monitor the reflective power that is reflected from the respective matching networks 110, 118. These devices are generally integrated into the matching networks 110, 118, or power supplies 112, 115; However, for descriptive purposes, they are shown here as being separate from the matching networks 110, 118. When reflected power is used as the indicator, the devices 150 and 152 are coupled between the supplies 112, 116 and the matching networks 110 and 118. To produce a signal indicative of reflected power, the devices 150 and 152 are directional couplers coupled to a RF detector such that the match effectiveness indicator signal is a voltage that represents the magnitude of the reflected power. A large reflected power is indicative of an unmatched situation. The signals produced by the devices 150 and 152 are coupled to the controller 114. In response to an indicator signal, the controller 114 produces a tuning signal (matching network control signal) that is coupled to the matching networks 110, 118. This signal is used to tune the capacitor or inductors in the matching networks 110, 118. The tuning process strives to minimize or achieve a particular level of, for example, reflected power as represented in the indicator signal. The matching networks 110, 118 typically may require between about 100 microseconds to about a few milliseconds to minimize reflected power from a plasma in a given steady state.

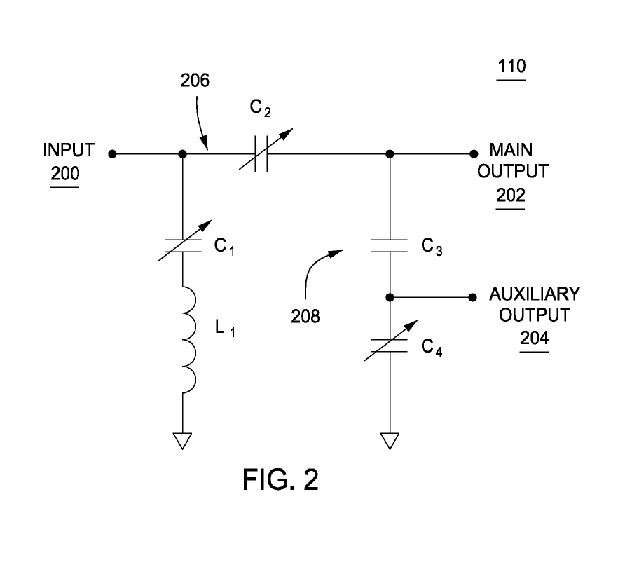

FIG. 2 depicts a schematic diagram of an illustrative matching network used, for example, as the first RF matching network 110 or second RF matching network 118. The matching network shown in FIG. 2 is just one example of a type of matching network that may be used in embodiments of the present invention. Other designs of matching networks may be used in embodiments of the present invention. The particular embodiment in FIG. 2 has a single input 200 and a dual output (i.e., main output 202 and auxiliary output 204). Each output is used to drive one of the two antennas. The matching circuit 206 is formed by C1, C2 and L1 and a capacitive power divider 208 is formed by C3 and C4. The capacitive divider values are set to establish a particular amount of power to be supplied to each antenna. In a mechanical or automatic tuning mode, values of capacitors C1 and C2 are automatically tuned to adjust the matching of the network 110. In some embodiments, while in automatic tuning mode, the capacitors may be adjusted to minimize reflected power. The values may be tuned by adjusting a position of either or both C1 and C2. Either C1 or C2 or both may be tuned to adjust the operation of the network. In a hold mode, the position, and thus the values, of C1 and C2 are held fixed.

Other embodiments of a matching network may have a tunable inductor or a different topology of variable or fixed elements such as capacitors and inductors. The source power that is matched by the network 110 is at about 13.56 MHz and has a power level of up to about 3000 watts. Such a matching network is available under model NAVIGATOR 3013-ICP85 from AE, Inc. of Fort Collins, Colo. Still other various configurations of match networks may be utilized in accordance with the teachings provided herein. Referring back to FIG. 1, the controller 114 comprises a central processing unit (CPU) 130, a memory 132 and support circuits 134. The controller 114 is coupled to various components of the plasma enhanced substrate processing system 100 to facilitate control of the process, such as an etch process or other suitable plasma-enhanced substrate process. The controller 114 regulates and monitors processing in the process chamber via interfaces that can be broadly described as analog, digital, wire, wireless, optical, and fiber optic interfaces. To facilitate control of the process chamber as described below, the CPU 130 may be one of any form of general purpose computer processor that can be used in an industrial setting for controlling various chambers and subprocessors. The memory 132 is coupled to the CPU 130. The memory 132, or a computer readable medium, may be one or more readily available memory devices such as random access memory, read only memory, floppy disk, hard disk, or any other form of digital storage either local or remote. The support circuits 134 are coupled to the CPU 130 for supporting the processor in a conventional manner. These circuits include cache, power supplies, clock circuits, input/output circuitry and related subsystems, and the like.

Etching, or other, process instructions are generally stored in the memory 132 as a software routine typically known as a process recipe. The software routine may also be stored and/or executed by a second CPU (not shown) that is remotely located from the hardware being controlled by the CPU 130. The software routine, when executed by CPU 130, transforms the general purpose computer into a specific purpose computer (controller) 114 that controls the system operation such as that for controlling the plasma during a substrate process, for example, an etch process. Although the process of the present invention can be implemented as a software routine, some of the method steps that are disclosed therein may be performed in hardware as well as by the software controller. As such, embodiments of the invention may be implemented in software as executed upon a computer system, and hardware as an application specific integrated circuit or other type of hardware implementation, or a combination of software and hardware.

Conventional matching networks and generators typically each contain control algorithms used for tuning the respective systems that are independent. Accordingly, each algorithm is not linked to the other with respect to the time or manner in which they both should be aiming to reduce the reflected power to the generator. The lack of such a link might cause a significant competition between the two tuning algorithms, and therefore, might cause system instabilities. In order to overcome this problem, in some embodiments of the present invention, an integrated matching network may be embedded within the RF generator with frequency tuning capability (e.g., the first or second RF source 112 or 116) while the algorithms used for tuning the matching network as well as the frequency with the RF cycle may both be controlled based on the same readings as measured at the generator output (e.g., using a shared sensor). By doing so, the competition between the two independent algorithms may be eliminated and the window of operation for the plasma reactors may be increased. In some embodiments, the first RF source 112 and the first matching network 110 (and/or the second RF source 116 and the second matching network 118) may be physically integrated or may merely share a controller directing the tuning process for the pair of devices to eliminate the tuning competition between the two and to maximize the tuning efficiency of the overall system. In some embodiments, the first RF source 112 and the first matching network 110 (and/or the second RF source 116 and the second matching network 118) may merely share a common sensor for reading the reflected power such that they are at least tuning to minimize reflected power off of the same reading.

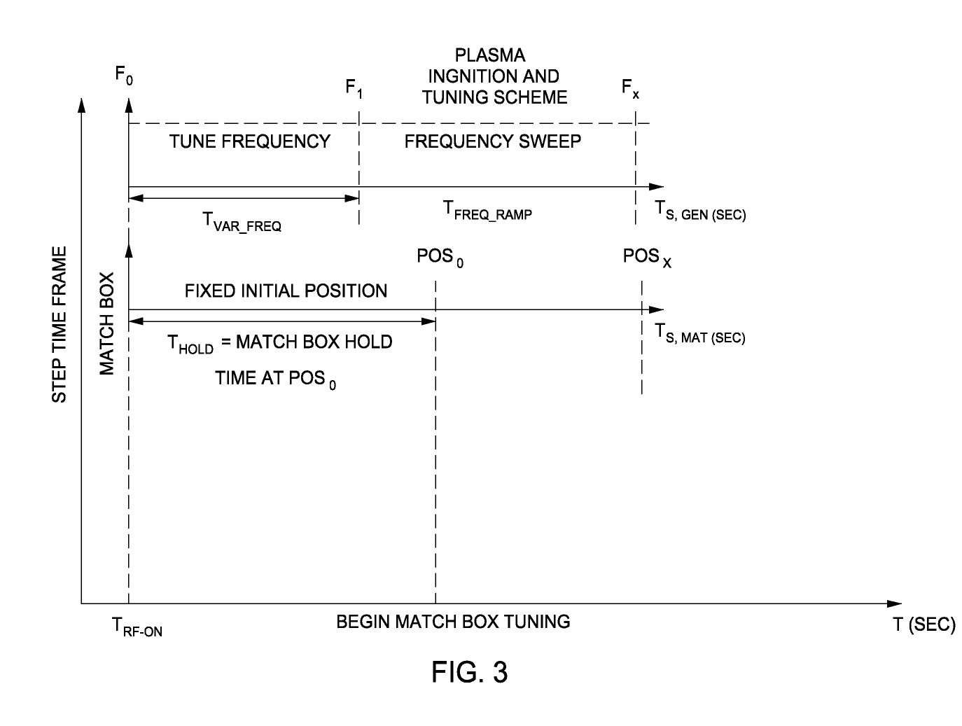

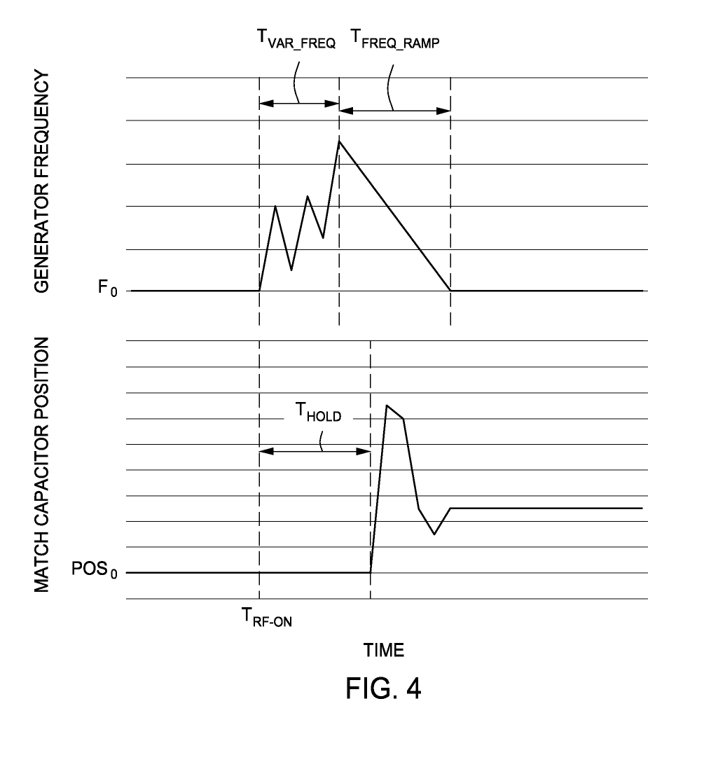

FIGS. 3 and 4 depicts a diagram of variables that may be independently controlled over time or set to predetermined values to facilitate fast and repeatable plasma ignition and matching the impedance of the plasma to the impedance of the RF source generator over a wide range of plasma processes. FIGS. 3 and 4 show time independent operational parameters for an RF source generator, such as first RF source 112, and a tunable matching network (i.e., a match box), such as first matching network 110. These parameters are decoupled and may be independently controlled. The RF source generator may be operated in a frequency sweep (or frequency tuning) mode. The matching network(i.e., match box) can be operated in autotuning mode or hold mode (in which the matching network fixes values/positions of components in the match and does not tune to minimize reflected power). Switching between each of these modes can be independently controlled to facilitate minimizing reflected power and stabilizing plasma processing during plasma processes across a wide process window.

In FIGS. 3 and 4, f₀ is the RF source generator starting RF frequency at Tₛₜₐᵣₜ; Tᵥₐᵣ_{_{—}}_{freq} is the time duration during which the RF source generator frequency allowed to tune after power on, power level change, or other transitions started at Tₛₜₐᵣₜ; T_{freq}_{_{—}}ᵣₐₘₚ is the time duration during which for the RF source generator frequency transitions back to f₀ or other known frequency value; T_{hold} is the time duration for the matching network to be fixed in hold mode; and Pos₀ is the initial fixed value/position of the matching network (e.g., in some embodiments, the fixed initial position of the capacitors in the matching network).

In FIG. 4, a timing diagram of frequencies is provided by the tunable matching circuits and RF generators in accordance with some embodiments. In FIG. 4, the RF generator starts outputting power, or changes its output level, at time Tₛₜₐᵣₜ, with f₀ starting RF frequency of the generator. In some embodiments, a plasma transition such as pressure change is started in the chamber at Tₛₜₐᵣₜ. In some embodiments, the starting RF frequency f₀ is a known predetermined value that may be within 5% to 10% of the generator center frequency. In some embodiments the generator center frequency could be about 2 MHz, 13.56 MHz or higher.

At this time the match box capacitors/inductors are held in a fixed position/value (Pos₀), while the generator frequency is allowed to tune to minimize reflected power. In some embodiments, a minimized reflected value may be about 0% to about 20% of the forward power, depending on the process and hardware requirements. In some embodiments, the lowest reflected power possible can be provided if the matching network operation is controlled properly. That is, the match can be controlled to be either one of two main modes: Automatic tuning mode or Hold mode (e.g., fixed position mode).

The RF generator frequency is allowed to tune for a duration of Tᵥₐᵣ_{_{—}}_{freq}. In some embodiments, Tᵥₐᵣ_{_{—}}_{freq} may be about 1 millisecond to about 1 second. During this period, the generator frequency will move away from the initial frequency f₀. At the end of this period, the generator will have frequency In some embodiments, the frequency may be adjusted from f₀ to f₁ in a non-monotonic manner. In some embodiments, the RF frequency f₁ may be about 5% to about 10% different from f₀. Although f₁ is shown as being a higher frequency than f₀, in some embodiments f₁ may be less than f₀. In some embodiments, at least one of f₀, f₁ and Tᵥₐᵣ_{_{—}}_{freq} are known predetermined values prior to the start of the ignition process. In other embodiments, the starting frequency f₀ and Tᵥₐᵣ_{_{—}}_{freq} are known predetermined values, while f₁ is not known. In some embodiments, the reflected power may be a predetermined threshold that, when reached, denotes the end of the Tᵥₐᵣ_{_{—}}_{freq} time period.

At time Tₛₜₐᵣₜ+Tᵥₐᵣ_{_{—}}_{freq}, the RF source generator frequency starts monotonically changing back towards the RF source generator starting frequency f₀. The transition from f₁ back towards f₀ may be linear or any other monotonic relation, and is completed within the time T_{freq-ramp}. In some embodiments, the T_{freq}_{_{—}}ᵣₐₘₚ time period may be about 10 milliseconds to about 1 second.

The frequency at the end of T_{freq}_{_{—}}ᵣₐₘₚ may be a third frequency fₓ that is not equal to f₀. In some embodiments, fₓ may be equal, or substantially equal, to f₀. In some embodiments, the RF frequency fₓ may be about 5% to about 10% different from f₀. In some embodiments, the third frequency fₓ and T_{freq}_{_{—}}ᵣₐₘₚ are known predetermined values, leading to a well defined final plasma and chamber condition at a specified time. The matching network is allowed to move/adjust values and tune after T_{hold} from Tₛₜₐᵣₜ. In some embodiments, the T_{hold} time period may be about 10 milliseconds to about 2 seconds. Although T_{hold} is shown in FIGS. 3 and 4 as ending after Tᵥₐᵣ_{_{—}}_{freq} (i.e., T_{hold}>Tᵥₐᵣ_{_{—}}_{freq}), in some embodiments the matching network is allowed to move/adjust values and tune during Tᵥₐᵣ_{_{—}}_{freq} (i.e., T_{hold}<Tᵥₐᵣ_{_{—}}_{freq}). After the sequence is completed, the RF source generator frequency is ramped back to fixed frequency fₓ, which may be equal to f₀ in some embodiments, and the matching network is automatically tuning.

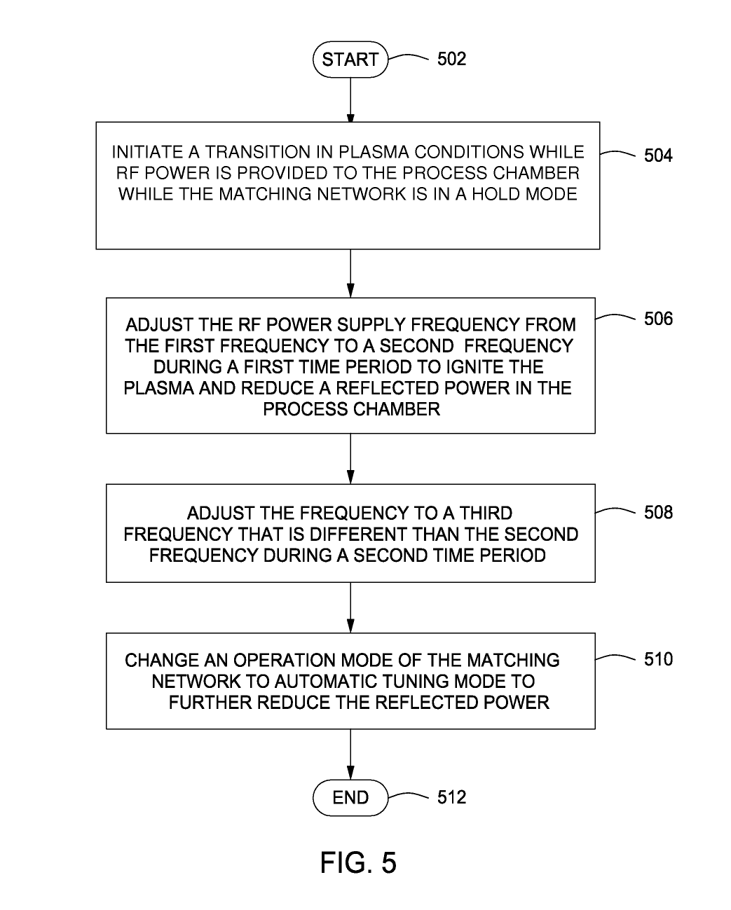

A method 500 in accordance with at least one exemplary embodiment of the present invention described above with respect to FIGS. 1-4 is illustrated in FIG. 5 which depicts a flowchart having a series of steps for igniting a plasma, or tuning across a plasma transition, and reducing a reflected power in a process chamber using a source RF power supply coupled to a process chamber via a matching network. In detail, the method 500 starts at 502 and proceeds to 504 where a transition in plasma conditions is initiated while RF power is provided to the process chamber by the RF power supply at a first frequency while the matching network is in a hold mode. The plasma transition may be initiated by the delivery of RF power, a change of the RF power level, a change of chemistry or pressure in the chamber, or other transition affecting the plasma. The first frequency may be f₀ as described above with respect to FIGS. 3 and 4. In a hold mode, the position and/or values of the matching network are held fixed.

At 506, the RF power supply frequency is adjusted from the first frequency (e.g., f₀) to a second frequency (e.g., f₁) during a first time period (e.g., Tᵥₐᵣ_{_{—}}_{freq}) to ignite the plasma or tune during a transition and reduce the reflected power in the process chamber using the RF power source. In some embodiments, the frequency may be increased, or decreased, from first frequency to the second frequency in a non-monotonic manner (that is, with possible intermediate frequencies during the first time period as shown in FIG. 4) and the plasma may be ignited at some frequency between the first frequency and the second frequency. The frequency may continue to be adjusted to the second frequency until the reflected power is minimized to a certain level during the first time period. During the first time period, the matching network is maintained in the hold mode.

At 508, the frequency is adjusted from the second frequency (e.g., f₁) to a third frequency (e.g., fₓ) during a second time period (e.g., T_{freq}_{_{—}}ᵣₐₘₚ). The third frequency is different from the second frequency and, in some embodiments, may be a predetermined known quantity (e.g., a target value). In some embodiments, at some point during the second time period, an operation mode of the matching network is changed from the hold mode to automatic tuning mode (e.g., after a T_{hold} time period, wherein T_{hold}>Tᵥₐᵣ_{_{—}}_{freq}) to further reduce the reflected power while the frequency provided by the RF power source is adjusted to the third known frequency at 510. In other embodiments, at some point during the first time period, an operation mode of the matching network is changed from the hold mode to automatic tuning mode (e.g., after a T_{hold} time period, wherein T_{hold}<Tᵥₐᵣ_{_{—}}_{freq}) to further reduce the reflected power while the frequency provided by the RF power source is adjusted to the third known frequency at 510.

The method 500 ends at 514.

While the foregoing is directed to embodiments of the present invention, other and further embodiments of the invention may be devised without departing from the basic scope thereof.

1. An apparatus for plasma processing in a process chamber, comprising:
a first RF power supply having frequency tuning;
a first matching network coupled to the first RF power supply; and
a controller to control the first RF power supply and the first matching network, wherein the controller is configured to:
initiate a plasma transition by at least one of instructing the RF power supply to provide RF power to the process chamber, instructing the RF power supply to change a level of RF power delivered to the process chamber, or changing a pressure in the process chamber, wherein the RF power supply operate at a first frequency and the matching network is in a hold mode;
instruct the RF power supply to adjust the first frequency to a second frequency during a first time period to ignite the plasma;
instruct the RF power supply to adjust the second frequency to a known third frequency during a second time period while maintaining the plasma; and
change an operational mode of the matching network to an automatic tuning mode to reduce a reflected power of the RF power provided by the RF power supply.

2. The apparatus of claim 1, wherein the first matching network is embedded within the first RF power supply, and wherein the controller controls both tuning of the first matching network as well as a frequency with an RF cycle based on a common reflected power reading provided by a common sensor as measured at an output of the first RF power supply.

3. The apparatus of claim 1, wherein the reflected power is reduced to between about 0% and 20% of a forward power provided by the RF power supply.

4. The apparatus of claim 1, wherein the first frequency is adjusted to the second frequency after the plasma is ignited to reduce reflected power from the RF power supply during the first time period.

5. The apparatus of claim 4, wherein a magnitude of the reflected power is a predetermined threshold that, when reached, denotes an end of the first time period.

6. The apparatus of claim 1, wherein the first time period is a known predetermined values.

7. A system for plasma processing in a process chamber, comprising:
a process chamber having an antenna assembly and a substrate support pedestal;
a first matching network coupled to the antenna assembly;
a first RF source coupled to the first matching network;
a matching network;
a second matching network coupled to the substrate support pedestal;
a second RF source coupled to the second matching network;
a controller to control the first RF source, the first matching network, the second RF source, and the second matching network, wherein the controller is configured to:
instructing the first RF source to provide RF power to the process chamber, wherein the first source operates at a first frequency and the first matching network is in a hold mode;
instruct the first RF source to adjust the first frequency to a second frequency during a first time period to ignite the plasma;
instruct the first RF source to adjust the second frequency to a known third frequency during a second time period while maintaining the plasma; and
change an operational mode of the first matching network to an automatic tuning mode to reduce a reflected power of the RF power provided by the first RF source.

8. A method for plasma processing in a process chamber using an RF power supply coupled to the process chamber via a matching network, the method comprising:
initiating a plasma transition by at least one of providing RF power to the process chamber, changing level of RF power delivered to the process chamber, or changing a pressure in the process chamber, wherein the RF power supply is operating at a first frequency and the matching network is in a hold mode;
adjusting the first frequency, using the RF power supply, to a second frequency during a first time period to ignite the plasma;
adjusting the second frequency, using the RF power supply, to a known third frequency during a second time period while maintaining the plasma; and
changing an operational mode of the matching network to an automatic tuning mode to reduce a reflected power of the RF power provided by the RF power supply.

9. The method of claim 8, wherein the matching network is maintained in the hold mode during the first time period.

10. The method of claim 8, wherein the operational mode of the matching network is changed to automatic tuning mode to reduce the reflected power while the second frequency is adjusted to the known third frequency during the second time period.

11. The method of claim 8, wherein the operational mode of the matching network is changed to automatic tuning mode during the first time period.

12. The method of claim 8, wherein the first frequency is adjusted to the second frequency after the plasma is ignited to reduce reflected power from the RF power supply during the first time period.

13. The method of claim 12, wherein a magnitude of the reflected power is a predetermined threshold that, when reached, denotes an end of the first time period.

14. The method of claim 8, wherein the reflected power is reduced to between about 0% and 20% of a forward power provided by the RF power supply.

15. The method of claim 8, wherein the first time period is a known predetermined value.

16. The method of claim 8, wherein adjusting the frequency from the first frequency to the second frequency occurs in a non-monotonic manner.

17. The method of claim 8, wherein adjusting the frequency from the second frequency to the third frequency occurs in a monotonic manner.

18. The method of claim 8, wherein the third frequency is substantially equal to the first frequency.

19. The method of claim 8, wherein the matching network includes adjustable capacitors, wherein the capacitors are held at a fixed first position in the hold mode, and wherein positions of the capacitors are moved in automatic tuning mode to reduce the reflected power.

20. The method of claim 8, wherein the first time period is less than about 100 milliseconds.
